(19) United States
(12) Patent Application Publication
(10) Pub. No.: US 2025/0266001 A1
(43) Pub. Date: Aug. 21, 2025

(54) DISPLAY DEVICE AND ELECTRONIC DEVICE INCLUDING THE SAME

(71) Applicant: Samsung Display Co., LTD., Yongin-si (KR)

(72) Inventors: Tae Soo KANG, Yongin-si (KR); Jin Seuk KIM, Yongin-si (KR); Hye Young KIM, Yongin-si (KR)

(21) Appl. No.: 18/882,413

(22) Filed: Sep. 11, 2024

(30) Foreign Application Priority Data
Feb. 21, 2024 (KR) 10-2024-0025165

(51) Int. Cl. G09G 3/3266; G09G 3/32

(52) U.S. Cl. CPC G09G 3/3266; G09G 3/32; G09G 2300/0426; G09G 2310/0267

(57) ABSTRACT

A display device includes a display panel having signal lines connected to one or more pixels, a plurality of connection pads provided to supply driving signals to the signal lines, one or more non-connection pads positioned to be adjacent to the plurality of connection pads and not connected to the signal lines, and a main controller for setting an individual voltage based on voltages of the driving signals and for applying a set individual voltage to the non-connection pad.

This application claims priority to Korean Patent Application No. 10-2024-0025165,filed on Feb. 21, 2024, and all the benefits accruing therefrom under 35 U.S.C. § 119, the content of which in its entirety is herein incorporated by reference.

### BACKGROUND

### Field

The invention relates to a display device, and more particularly to a display device and an electronic device including the same.

### Description of the Related Art

A display device may include a display panel that outputs an image and a driving circuit that provides signals for driving the display panel. The driving circuit may be electrically connected to the display panel through one or more pads to provide a plurality of signals to the display panel.

Voltages of different magnitudes may be applied to the pads. In this case, corrosion may occur in any one of the pads due to a potential difference that occurs between neighboring pads. Corrosion occurring in the pads can lead to increased resistance, disconnection, short circuit, poor bonding, and the like, and can act as a factor that deteriorates the operational reliability of the display device.

### SUMMARY

An aspect of the invention is to provide a display device that can improve the operational reliability by preventing corrosion from occurring in the pads that are included in a driving circuit.

A display device, according to an embodiment, may include a display panel having signal lines connected to one or more pixels, a plurality of connection pads provided to supply driving signals to the signal lines, one or more non-connection pads positioned adjacent to the plurality of connection pads and not connected to the signal lines and a main controller for setting an individual voltage based on voltages of the driving signals and for applying a set individual voltage to the non-connection pad.

In an embodiment, the display device may further include one or more switches disposed between any one of the connection pads and the non-connection pad.

In an embodiment, the main controller may turn off the switch.

In an embodiment, the magnitude of the individual voltage may be the same as magnitudes of the voltages of the driving signals.

In an embodiment, the individual voltage may be a ground voltage.

In an embodiment, the connection pads may include a (1_1)th pad and a (1_2)th pad which are sequentially arranged in a first direction, and the non-connection pad may include a (2_2)th pad which is arranged to be spaced apart from the (1_2)th pad in a second direction which intersects the first direction.

In an embodiment, the connection pads may further include a (2_1)th pad which is spaced apart from the (1_1)th pad in the second direction and which is spaced apart from the (2_2)th pad in a direction that is opposite to the first direction.

In an embodiment, the display device may further include a (1_2)th switch which is disposed between the (2_1)th pad and the (2_2)th pad, wherein the main controller may turn off the (1_2)th switch.

In an embodiment, the connection pads may further include a (3_1)th pad what is arranged to be spaced apart from the (2_1)th pad in the second direction and a (3_2)th pad which is arranged to be spaced apart from the (2_2)th pad in the second direction.

In an embodiment, the main controller may set a magnitude of the individual voltage that is applied to the (2_2)th pad based on a magnitude of a first voltage that is applied to the (1_2)th pad and a magnitude of a second voltage that is applied to the (3_2)th pad according to the driving signals.

In an embodiment, the magnitude of the individual voltage that is applied to the (2_2)th pad may be an average value of the magnitude of the first voltage and the magnitude of the second voltage.

In an embodiment, the connection pads may include a (2_1)th sub-pad arranged between the (2_1)th pad and the (3_1)th pad in the first direction, and the non-connection pads may include a (2_2)th sub-pad arranged between the (2_2)th pad and the (3_2)th pad in the first direction.

In an embodiment, the main controller may set the magnitude of the individual voltage that is applied to the (2_2)th pad and the (2_2)th sub-pad based on the magnitude of the first voltage that is applied to the (1_2)th pad and the magnitude of the second voltage that is applied to the (3_2)th pad according to the driving signals.

In an embodiment, the connection pads may further include a (3_3)th pad which is arranged to be spaced apart from the (3_2)th pad in the first direction, and the non-connection pads may further include a (1_3)th pad which is arranged to be spaced apart from the (1_2)th pad in the first direction, and a (2_3)th pad which is arranged to be spaced apart from the (2_2)th pad in the first direction.

In an embodiment, the display device may further include a scan driver which generates a scan signal that is one of the drive signals, wherein the scan driver may supply the scan signal to the one or more pixels through the signal lines.

A display device, according to an embodiment, may include a display panel having signal lines connected to one or more pixels, a plurality of connection pads provided to supply driving signals to the signal lines, a non-connection pad positioned to be adjacent to the plurality of connection pads and not connected to the signal lines and a main controller for applying an individual voltage having a voltage value between a highest voltage value and a lowest voltage value among voltages of the driving signals applied to the non-connection pad.

An electronic device including a display device, according to an embodiment, may include a processor providing input image data to a display device where the display device displays an image based on the input image data. The display device may include a display panel having signal lines connected to one or more pixels, a plurality of connection pads provided to supply driving signals to the signal lines, one or more non-connection pads positioned adjacent to the plurality of connection pads and not connected to the signal lines and a main controller for setting an individual voltage which is based on voltages of the driving signals and for applying a set individual voltages to the non-connection pad.

In an embodiment, the electronic device may further include one or more switches disposed between any one of the connection pads and the non-connection pad.

In an embodiment, the main controller may turn off the switch.

In an embodiment, a magnitude of the individual voltage may be the same as magnitudes of the voltages of the driving signals.

### BRIEF DESCRIPTION OF THE DRAWINGS

The accompanying drawings, which are included to provide a further understanding of the invention, and which are incorporated in and constitute a part of this specification, illustrate exemplary embodiments of the invention, and, together with the description, serve to explain principles of the invention.

FIG. 1 is a plan view of a display panel, according to an embodiment.

FIG. 2 is a plan view of the display panel illustrating the connection relationship between pixels and a pad area shown in FIG. 1, according to an embodiment.

FIG. 3 is a plan view illustrating a display device, according to an embodiment.

FIG. 4 is a block diagram illustrating the display device, according to an embodiment.

FIG. 5 is a schematic circuit diagram illustrating an embodiment of one of the pixels included in the display device of FIG. 4, according to an embodiment.

FIG. 6 is a plan view illustrating an embodiment of a driving circuit shown in FIG. 3, according to an embodiment.

FIG. 7A is a plan view illustrating a first area shown in FIG. 6, according to an embodiment.

FIG. 7B is a plan view illustrating a first area shown in FIG. 6, according to an embodiment.

FIG. 7C is a plan view illustrating a first area shown in FIG. 6, according to an embodiment.

FIG. 8A is a table illustrating a gate voltage applied to connection pads and an individual voltage applied to a non-connection pad in FIG. 7A, according to an embodiment.

FIG. 8B is a table illustrating the gate voltage applied to the connection pads and the individual voltage applied to the non-connection pad in FIG. 7A, according to an embodiment.

FIG. 9 is a plan view illustrating the first area shown in FIG. 6, according to an embodiment.

FIG. 10A is a table illustrating a gate voltage applied to connection pads and an individual voltage applied to a non-connection pad in FIG. 9, according to an embodiment.

FIG. 10B is a table illustrating the gate voltage applied to the connection pads and the individual voltage applied to the non-connection pad in FIG. 9, according to an embodiment.

FIG. 11 is a plan view illustrating a second area shown in FIG. 6, according to an embodiment.

FIG. 12 is a block diagram illustrating an electronic device including a display device, according to an embodiment.

FIG. 13 is a perspective view illustrating an example in which the electronic device of FIG. 12 is implemented as a smartphone, according to an embodiment.

FIG. 14 is a perspective view illustrating an example in which the electronic device of FIG. 12 is implemented as a tablet PC, according to an embodiment.

### DETAILED DESCRIPTION

Hereinafter, embodiments of the invention will be described in detail with reference to the accompanying drawings. The following description is intended to provide a sufficient disclosure to enable the understanding of the invention. In addition, the invention may be embodied in different forms and is not limited to the embodiments set forth herein. The embodiments described herein are provided for the purpose of describing the invention in sufficient detail for those skilled in the art to easily practice the invention.

Throughout the specification, when it is described that an element is “connected” to another element, this includes not only being “directly connected”, but also being “indirectly connected” with another device in between. The terms used herein are for the purpose of describing specific embodiments and are not intended to limit the scope of the invention. Throughout the specification, unless explicitly described to the contrary, the word “comprise” and variations such as “comprises” or “comprising” will be understood to imply the inclusion of stated elements but not the exclusion of any other elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various constituent elements, these constituent elements should not be limited by these terms. These terms are used to distinguish one constituent element from another constituent element. Thus, a first constituent element discussed below could be termed a second constituent element without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments may be described herein with reference to sectional illustrations that are schematic illustrations of idealized embodiments. As such, variations from the shapes of the illustrations as a result, for example, of manufacturing techniques and/or tolerances, are to be expected. Thus, embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

Like numbers refer to like elements throughout. In the drawings, the thickness of certain lines, layers, components, elements or features may be exaggerated for clarity. It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the invention.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Hereinafter, embodiments of the invention will be described in detail with reference to the accompanying drawings.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

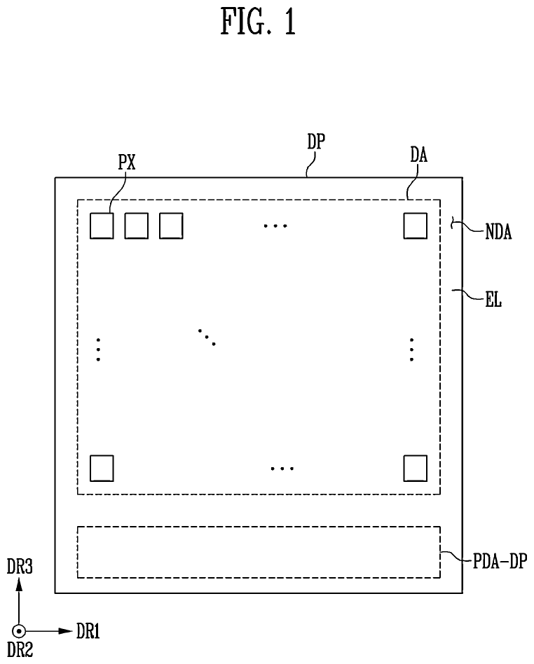

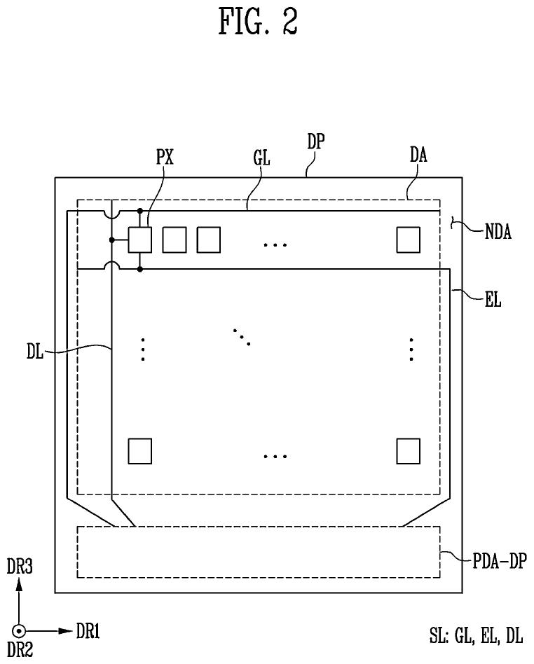

FIG. 1 is a plan view of a display panel, according to an embodiment. FIG. 2 is a plan view of the display panel illustrating the connection relationship between pixels and a pad area shown in FIG. 1, according to an embodiment.

In an embodiment and referring to FIG. 1, a display panel DP may be a light emitting type display panel. However, the invention is not limited thereto. For example, the display panel DP may be an organic light emitting display panel or a quantum dot light emitting display panel. In an organic light emitting display panel, a light emitting layer may include an organic light emitting material. In a quantum dot light emitting display panel, a light emitting layer may include quantum dots and quantum rods. Hereinafter, the display panel DP will be described as an organic light emitting display panel.

In an embodiment, the display panel DP may include a display area DA and a non-display area NDA disposed adjacent to the display area DA. The non-display area NDA may be an area where an image is not displayed. As an example, the display area DA may be defined as an area where pixels PX are arranged to provide image information to users. The non-display area NDA may be a peripheral area of the display area DA and may surround the display area DA. For example, the non-display area NDA may be defined as an area where wirings and electronic components for driving the pixels PX are disposed.

The non-display area NDA may include a first pad area PDA-DP. A plurality of pads may be disposed in the first pad area PDA-DP. For example, the plurality of pads may be arranged in a first direction DR1 in the first pad area PDA-DP and the display panel DP may receive an electrical signal from outside through the plurality of pads.

In an embodiment, a plurality of pixels PX may be arranged in a matrix form along a first direction DR1 and a second direction DR2, where first direction DR1 and second direction DR2 are orthogonal to each other. In FIG. 1, a pixel PX is shown as having a square shape, but the invention is not limited thereto. The shape of the pixel PX may be changed in various ways, such as polygonal, circular, or oval.

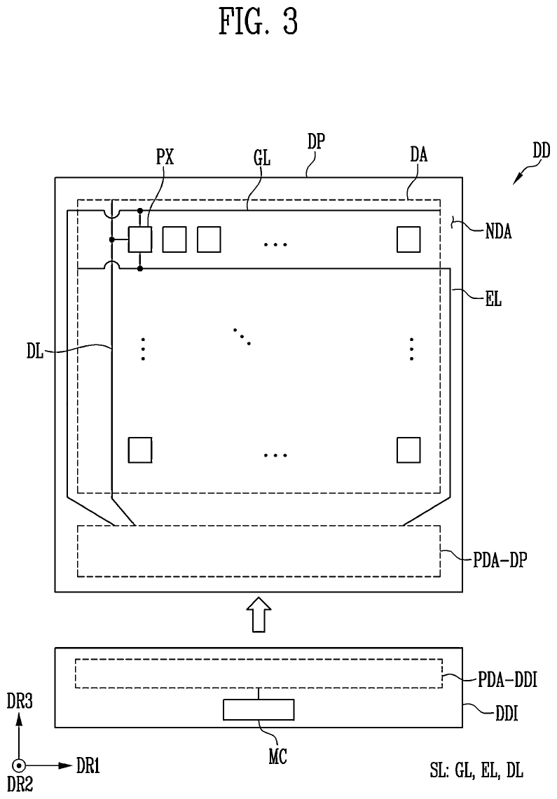

In an embodiment and referring to FIG. 2, each of the pixels PX may be connected to the first pad area PDA-DP through a signal line SL. Each of the pixels PX may be connected to one of signal lines SL. For example, each of the pixels PX may be connected to any one of an emission line EL, a data line DL, and a scan line GL. Accordingly, each of the pixels PX may receive a plurality of signals and/or voltages. Hereinafter, this will be described in detail below with reference to FIGS. 3 to 5.

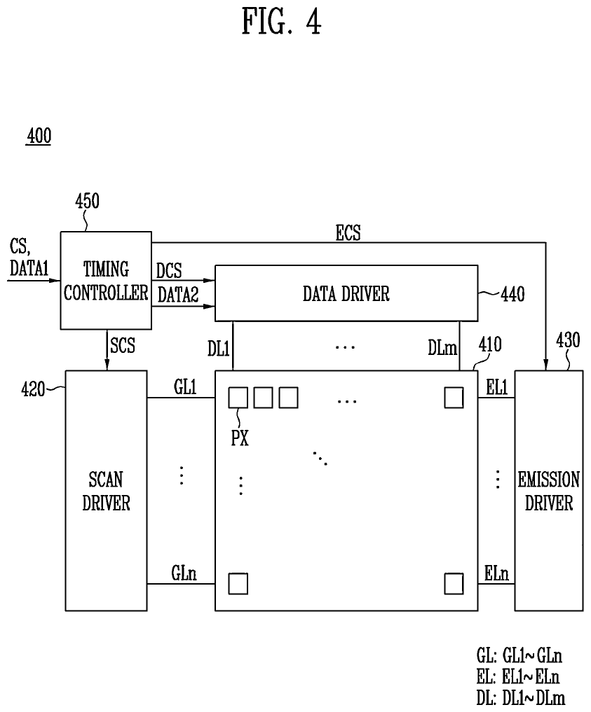

FIG. 3 is a plan view illustrating a display device, according to an embodiment. FIG. 4 is a block diagram illustrating the display device, according to an embodiment.

In an embodiment and referring to FIG. 3, a display device DD may include a display panel DP and a driving circuit DDI. The display panel DP of FIG. 3 may be the same or similar to the display panel DP of FIG. 2. Hereinafter, overlapping descriptions will be omitted.

The display panel DP may include a substrate for supporting the display panel DP. According to an embodiment, the substrate may be a rigid substrate made of glass. In another embodiment, the substrate may be a flexible substrate capable of bending, folding, rolling, or the like. In this case, the substrate may include an insulating material including a polymer resin such as polyimide.

According to an embodiment, the substrate may include a silicon wafer substrate formed through a semiconductor process. The substrate may include a semiconductor material suitable for forming circuit elements. For example, the semiconductor material may include silicon, germanium, and/or silicon-germanium. The substrate may be provided from a bulk wafer, an epitaxial layer, a silicon on insulator (SOI) layer, or a semiconductor on insulator (SeOI) layer.

In an embodiment, the driving circuit DDI may be disposed on the display panel DP. For example, the driving circuit DDI may be disposed on the substrate described above. In other words, the driving circuit DDI may be disposed on the display panel DP (or substrate) using a chip-on plastic (COP) method. However, the invention is not limited thereto. For example, in another embodiment, the driving circuit DDI may be disposed on the display panel DP using a chip-on glass (COG) method.

In an embodiment, the driving circuit DDI may include a second pad area PDA-DDI. For example, the driving circuit DDI may include the second pad area PDA-DDI including a plurality of pads.

The driving circuit DDI may be connected to the display panel DP. For example, the first pad area PDA-DP and the second pad area PDA-DDI may overlap each other. Accordingly, pads of each of the first pad area PDA-DP and the second pad area PDA-DDI may contact each other. Accordingly, the driving circuit DDI may be electrically connected to the display panel DP through the plurality of pads.

The driving circuit DDI may include a main controller MC, where the main controller MC may supply a plurality of signals to the second pad area PDA-DDI. For example, the main controller MC may provide various voltages and/or signals. Accordingly, the main controller MC may supply voltages and/or signals to the signal lines SL through the second pad area PDA-DDI and the first pad area PDA-DP.

In an embodiment and referring to FIG. 4, a display device 400 may include a display panel 410, a scan driver 420, an emission driver 430, a data driver 440, and a timing controller 450. The display device 400 and display panel 410 of FIG. 4 may be the same as the display device DD and display panel DP of FIG. 3. Hereinafter, overlapping descriptions will be omitted.

In an embodiment, the scan driver 420 may be configured to supply a scan signal to a plurality of scan lines GL1˜GLn, where n may be an integer greater than or equal to 1. According to an embodiment, the scan driver 420 may be configured to sequentially supply the scan signal to the plurality of scan lines GL1˜GLn, but the invention is not limited thereto. The scan driver 420 may receive a scan driving signal SCS and may supply the scan driving signal to the plurality of scan lines GL1˜GLnaccording to timing.

The emission driver 430 may be configured to supply an emission signal to a plurality of emission lines EL1 to Eln. According to an embodiment, the mission driver 430 may be configured to sequentially supply the emission signal to the plurality of emission lines EL1 to Eln, but the invention is not limited thereto. The emission driver 430 may receive an emission driving signal ECS and supply the emission signal to the plurality of emission lines EL1 to Eln according to timing.

In an embodiment, the data driver 440 may be configured to supply (apply or output) a data voltage to a plurality of data lines DL1 to DLm, where m may be an integer greater than or equal to 1. The data driver 440 may receive a data driving signal DCS and second image data DATA2 and supply the data voltage corresponding to the image data to the plurality of data lines DL1 to DLm according to timing.

In an embodiment, the timing controller 450 may receive a control signal CS and first image data DATA1 from an external source (for example, a processor). The timing controller 450 may output the data driving signal DCS, the scan driving signal SCS, the emission driving signal ECS, and the second image data DATA2 based on the input control signal CS and first image data DATA1. For example, the timing controller 450 may convert the supplied first image data DATA1 into the second image data DATA2. Thereafter, the timing controller 450 may transmit the second image data DATA2 to the data driver 440.

According to an embodiment, the driving circuit DDI may include at least one of the scan driver 420, the emission driver 430, the data driver 440, and the timing controller 450. For example, two or more components among the scan driver 420, the emission driver 430, the data driver 440, and the timing controller 450 may be mounted within one integrated circuit. However, the invention is not limited thereto.

In an embodiment and referring again to FIGS. 3 and 4, the scan driver 420 included in the driving circuit DDI may supply the scan signal to the scan line GL through the second pad area PDA-DDI and the first pad area PDA-DP. In addition, the emission driver 430 included in the driving circuit DDI may supply the emission signal to the emission line EL through the second pad area PDA-DDI and the first pad area PDA-DP. According to an embodiment, the data driver 440 included in the driving circuit DDI may supply the data voltage (or data signal) to the data line DL through the second pad area PDA-DDI and the first pad area PDA-DP.

According to an embodiment, the driving circuit DDI may include power generating circuits that supply power sources necessary to drive the display panel DP. For example, the driving circuit DDI may include the power generating circuits that supply a predetermined power source to the scan driver 420. Accordingly, the scan driver 420 may generate the scan signal using the supplied power source. However, the invention is not limited thereto. For example, in another embodiment, the display device DD may receive power sources from an external source.

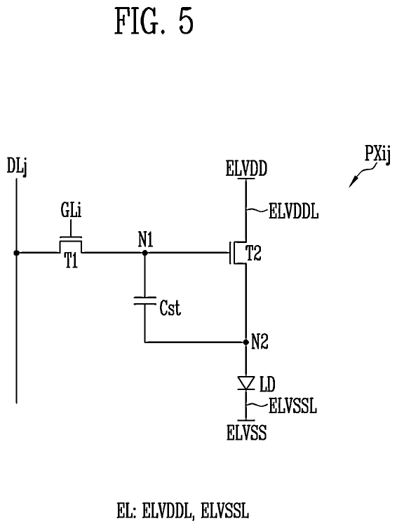

FIG. 5 is a circuit diagram illustrating an embodiment of one of pixels included in the display device of FIG. 4.

In an embodiment and referring to FIG. 5, a pixel PXij may include one or more transistors, one or more capacitors, and a light emitting element. In this case, the pixel PXij of FIG. 5 may be the same as the pixel PX shown in FIG. 4. For example, the pixel PXij of FIG. 5 may be a pixel PXij located in an i-th pixel row and a j-th pixel column among the pixels PX shown in FIG. 4, where i and j may be integers greater than or equal to 1.

Hereinafter, an embodiment where transistors T1 and T2 are composed of N-type transistors (for example, n-channel metal oxide semiconductor (NMOS) transistors) will be described. However, in another embodiment, the transistors T1 and T2 may be composed of P-type transistors (for example, p-channel metal oxide semiconductor (PMOS) transistors) or a combination of an N-type transistor and a P-type transistor.

In an embodiment, a gate electrode of a first transistor T1 may be connected to an i-th scan line GLi. One electrode of the first transistor T1 may be connected to a first node N1 and the other electrode of the first transistor T1 may be connected to a j-th data line DLj. The first transistor T1 may be referred to as a switching transistor or the like. However, the invention is not limited thereto.

In an embodiment, a gate electrode of a second transistor T2 may be connected to the first node N1. One electrode of the second transistor T2 may be connected to a first power source line ELVDDL to which a first power source voltage ELVDD is applied and the other electrode of the second transistor T2 may be connected to a second node N2.

In an embodiment, one electrode of a storage capacitor Cst may be connected to the first node N1 and the other electrode of the storage capacitor Cst may be connected to the second node N2.

In an embodiment, an anode of a light emitting element LD may be connected to the second node N2 and a cathode of the light emitting element LD may be connected to a second power source line ELVSSL to which a second power source voltage ELVSS is applied. The light emitting element LD may be composed of a light emitting diode. For example, the light emitting element LD may be an organic light emitting diode. However, the invention is not limited thereto. For example, in another embodiment, the light emitting element LD may be composed of an inorganic light emitting diode, a quantum dot light emitting diode, or the like.

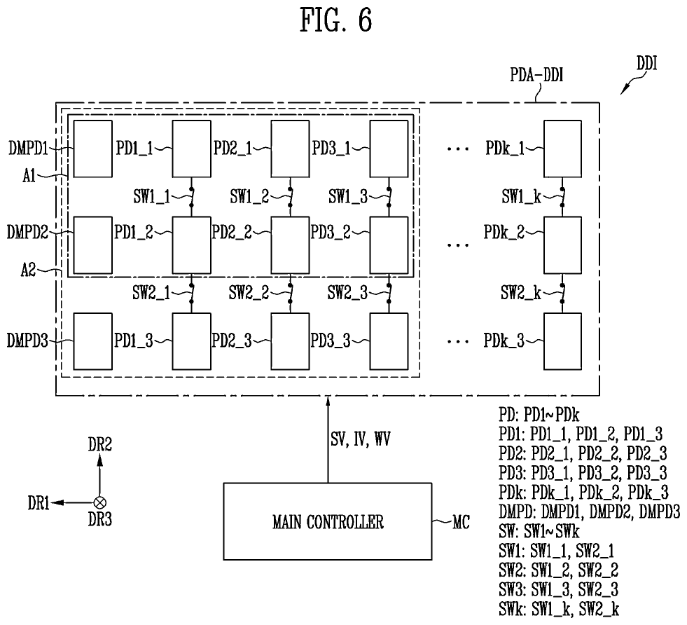

FIG. 6 is a plan view illustrating an embodiment of a driving circuit shown in FIG. 3.

In an embodiment and referring to FIG. 6, the driving circuit DDI may include the second pad area PDA-DDI and the main controller MC.

The second pad area PDA-DDI may include a plurality of pads PD. For example, the second pad areas PDA-DDI may include first to k-th pads PD1 to PDk which are spaced apart from each other in the first direction DR1 and arranged in the second direction DR2, where k may be an integer greater than or equal to 1.

Each of the first to k-th pads PD1 to PDk may be composed of three rows of pads PD. For example, the first pads PD1 may include a (1_1)th pad PD1_1, a (1_2)th pad PD1_2, and a (1_3)th pad PD1_3 sequentially arranged in a direction opposite to the second direction DR2. The second pads PD2 may include a (2_1)th pad PD2_1, a (2_2)th pad PD2_2, and a (2_3)th pad PD2_3 sequentially arranged in a direction opposite to the second direction DR2. In addition, the third pads PD3 may include a (3_1)th pad PD3_1, a (3_2)th pad PD3_2, and a (3_3)th pad PD3_3 sequentially arranged in a direction opposite to the second direction DR2. Furthermore, the k-th pads PDk may include a (k_1)th pad PDk_1, a (k_2)th pad PDk_2, and a (k_3)th pad PDk_3 sequentially arranged in a direction opposite to the second direction DR2. However, this is only an example, and the invention is not limited thereto. For example, in another embodiment, each of the first to k-th pads PD1 to PDk may be composed of two rows of pads PD, and the positional relationship between the pads PD may also be different.

In an embodiment, the second pad area PDA-DDI may include a plurality of dummy pads DMPD. For example, the plurality of dummy pads DMPD may include a first dummy pad DMPD1, a second dummy pad DMPD2, and a third dummy pad DMPD3 sequentially arranged in a direction opposite to the second direction DR2. In other words, the dummy pads DMPD may be composed of three rows of dummy pads DMPD. However, the invention is not limited thereto. For example, in another embodiment, the dummy pads DMPD may be composed of two rows of dummy pads DMPD.

In an embodiment, the dummy pads DMPD may receive a ground voltage from the main controller MC. However, the invention is not limited thereto. For example, in another embodiment, the dummy pads DMPD may be controlled to be in a floating state.

In an embodiment, the second pad area PDA-DDI may include a plurality of switches SW. For example, the second pad area PDA-DDI may include the switches SW that control electrical connections between the plurality of pads. According to an embodiment, the switches SW may be implemented in the form of transistors. However, the invention is not limited thereto.

In an embodiment, the switches SW may include first to k-th switches SW1 to SWk respectively disposed between the first to k-th pads PD1 to PDk. For example, the switches SW may include a first switch SW1 which is arranged in a direction opposite to the second direction DR2 and which is disposed between the first pads PD1.

The first switch SW1 may include a (1_1)th switch SW1_1 disposed between the (1_1)th pad PD1_1 and the (1_2)th pad PD1_2. In addition, the first switch SW1 may include a (2_1)th switch SW2_1 disposed between the (1_2)th pad PD1_2 and the (1_3)th pad PD1_3.

The second switch SW2 may include a (1_2)th switch SW1_2 and a (2_2)th switch SW2_2 sequentially arranged in a direction opposite to the second direction DR2 and respectively disposed between the second pads PD2.

The third switch SW3 may include a (1_3)th switch SW1_3 and a (2_3)th switch SW2_3 sequentially arranged in a direction opposite to the second direction DR2 and respectively disposed between the third pads PD3.

Furthermore, the k-th switch SWk may include a (1_k)th switch SW1_k and a (2_k)th switch SW2_k sequentially arranged in a direction opposite to the second direction DR2 and respectively disposed between the k-th pads PDk.

In an embodiment, the main controller MC may supply at least one signal and/or voltage to the plurality of pads PD which are arranged in the second pad area PDA-DDI. For example, the main controller MC may apply a voltage SV to the plurality of pads PD according to a driving signal. In other words, the voltage SV according to the driving signal supplied to the display panel DP (see FIG. 4) by the main controller MC may be applied to at least one of the pads PD.

The main controller MC may apply an individual voltage IV to the second pad area PDA-DDI. For example, the main controller MC may provide the individual voltage IV to one of the plurality of pads PD. In this case, the main controller MC may set the magnitude of the individual voltage IV based on the voltage SV according to driving signals.

In an embodiment, the main controller MC may provide a switch voltage WV to the second pad area PDA-DDI. The switch voltage WV may be a voltage required to drive the switch SW. For example, the main controller MC may apply the switch voltage WV according to a signal driving each of the plurality of switches SW to the second pad area PDA-DDI. Accordingly, each of the switches SW may be controlled by receiving the switch voltage WV.

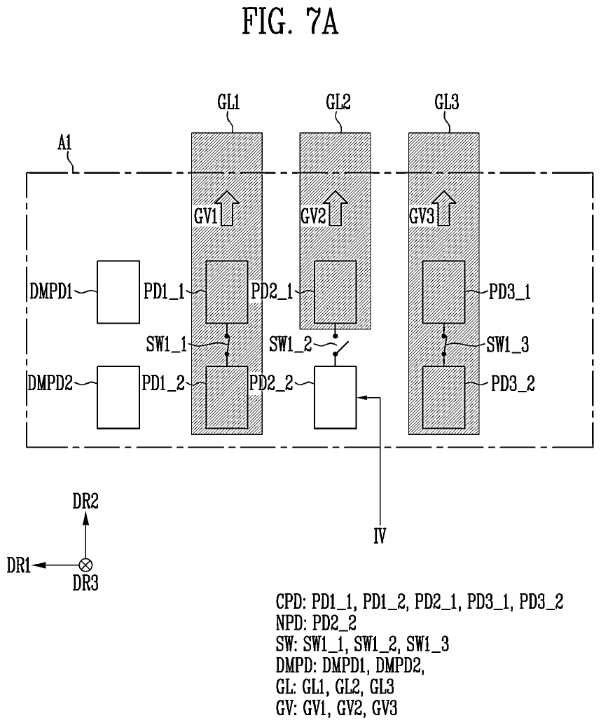

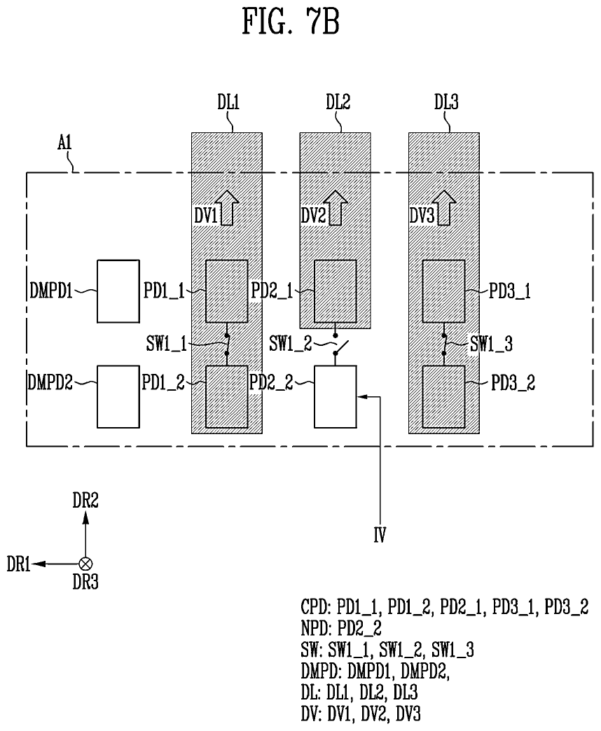

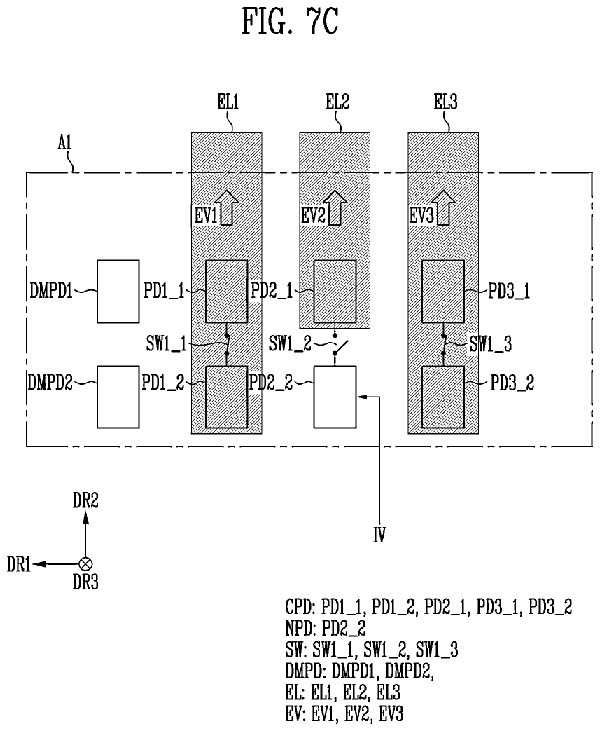

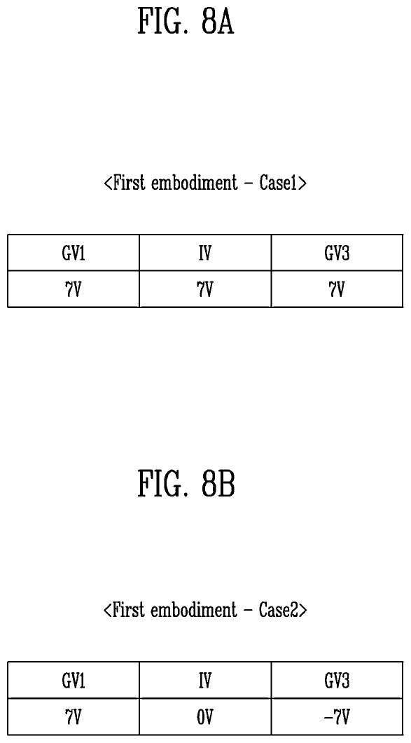

FIGS. 7A to 7C are plan views illustrating embodiments of a first area shown in FIG. 6. FIG. 8A is a diagram illustrating an embodiment of a gate voltage applied to connection pads and an individual voltage applied to a non-connection pad in FIG. 7A. FIG. 8B is a diagram illustrating an embodiment of the gate voltage applied to the connection pads and the individual voltage applied to the non-connection pad in FIG. 7A.

In an embodiment and referring to FIG. 7A, a first area A1 may include at least one connection pad CPD connected to the scan line GL. The connection pads CPD may include the (1_1)th pad PD1_1 and the (1_2)th pad PD1_2 connected to a first scan line GL1. In addition, the connection pads CPD may include the (2_1)th pad PD2_1 connected to a second scan line GL2. As another example, the connection pads CPD may include the (3_1)th pad PD3_1 and the (3_2)th pad PD3_2 connected to a third scan line GL3.

The first area A1 may include at least one non-connection pad NPD that is not connected to the scan line GL. For example, the non-connection pad NPD may include the (2_2)th pad PD2_2 that is not connected to the second scan line GL2.

In an embodiment, each of the connection pads CPD connected to the first to third scan lines GL1 to GL3 may receive a gate voltage GV. For example, the (1_1)th pad PD1_1 and the (1_2)th pad PD1_2 connected to the first scan line GL1 may receive a first gate voltage GV1. In addition, the (2_1)th pad PD2_1 connected to the second scan line GL2 may receive a second gate voltage GV2. The (3_1)th pad PD3_1 and the (3_2)th pad PD3_2 connected to the third scan line GL3 may receive a third gate voltage GV3.

In an embodiment, the main controller MC (see FIG. 6) may apply the first to third gate voltages GV1 to GV3 to the connection pads CPD. According to an embodiment, the first to third gate voltages GV1 to GV3 may be voltages corresponding to the scan signal provided to the plurality of scan lines GL1˜GLn (see FIG. 4) by the scan driver 420 (see FIG. 4).

Referring to FIG. 7B, according to an embodiment, the first area A1 may include at least one connection pad CPD connected to the data line DL. The connection pads CPD may include the (1_1)th pad PD1_1 and the (1_2)th pad PD1_2 connected to a first data line DL1. In addition, the connection pads CPD may include the (2_1)th pad PD2_1 connected to a second data line DL2. As another example, the connection pads CPD may include the (3_1)th pad PD3_1 and the (3_2)th pad PD3_2 connected to a third data line DL3.

The first area A1 may include at least one non-connection pad NPD that is not connected to the data line DL. For example, the non-connection pad NPD may include the (2_2)th pad PD2_2 that is not connected to the second data line DL2.

Each of the connection pads CPD connected to the first to third data lines DL1 to DL3 may receive a data voltage DV. For example, the (1_1)th pad PD1_1 and the (1_2)th pad PD1_2 connected to the first data line DL1 may receive a first data voltage DV1. In addition, the (2_1) pad PD2_1 connected to the second data line DL2 may receive a second data voltage DV2. The (3_1)th pad PD3_1 and the (3_2)th pad PD3_2 connected to the third data line DL3 may receive a third data voltage DV3.

In an embodiment, the main controller MC (see FIG. 6) may apply the first to third data voltages DV1 to DV3 to the connection pads CPD. According to an embodiment, the data voltage DV may correspond to the data voltage provided to the plurality of data lines DL1 to DLn (see FIG. 4) by the data driver 440 (see FIG. 4).

In an embodiment and referring to FIG. 7C, the first area A1 may include at least one connection pad CPD connected to the emission line EL. The connection pads CPD may include the (1_1)th pad PD1_1 and the (1_2)th pad PD1_2 connected to a first emission line EL1. In addition, the connection pads CPD may include the (2_1)th pad PD2_1 connected to a second emission line EL2. As another example, the connection pads CPD may include the (3_1)th pad PD3_1 and the (3_2)th pad PD3_2 connected to a third emission line EL3.

The first area A1 may include at least one non-connection pad NPD that is not connected to the emission line EL. For example, the non-connection pad NPD may include the (2_2)th pad PD2_2 that is not connected to the second emission line EL2.

In an embodiment, each of the connection pads CPD connected to the first to third emission lines EL1 to EL3 may receive an emission voltage EV. For example, the (1_1)th pad PD1_1 and the (1_2)th pad PD1_2 connected to the first emission line EL1 may receive a first emission voltage EV1. In addition, the (2_1)th pad PD2_1 connected to the second emission line EL2 may receive a second emission voltage EV2. The (3_1)th pad PD3_1 and the (3_2) pad PD3_2 connected to the third emission line EL3 may receive a third emission voltage EV3.

In an embodiment, the main controller MC (see FIG. 6) may apply the first to third emission voltages EV1 to EV3 to the connection pads CPD. According to an embodiment, the first to third emission voltages EV1 to EV3 may be voltages corresponding to the emission signal provided to the plurality of emission lines EL1 to ELn (see FIG. 4) by the emission driver 430 (see FIG. 4).

In an embodiment and referring to FIGS. 7A to 7C, the first area A1 may include the first dummy pad DMPD1 and the second dummy pad DMPD2. In FIGS. 7A to 7C, the first dummy pad DMPD1 and the second dummy pad DMPD2 are shown as being disposed at one end of the first area A1 in the first direction DR1, but the invention is not limited thereto.

Hereinafter, for convenience of description, an embodiment where the connection pads CPD are connected to one of the scan lines GL will be described as an example. However, the invention is not limited thereto.

In an embodiment and referring to FIG. 7A, the main controller MC (see FIG. 6) may drive each of the switches SW disposed in the first area A1. In other words, each of the switches SW may be controlled according to the switch voltage WV (see FIG. 6) applied from the main controller MC. For example, the switch SW may include the (1_1)th switch SW1_1 disposed between the (1_1)th pad PD1_1 and the (1_2)th pad PD1_2. In this case, the main controller MC may turn on the (1_1)th switch SW1_1. Accordingly, the (1_1)th pad PD1_1 and the (1_2)th pad PD1_2 may be electrically connected to each other. In other words, a voltage (for example, the first gate voltage GV1) having the same magnitude may be applied to the (1_1)th pad PD1_1 and the (1_2)th pad PD1_2.

Additionally, the switch SW may include the (1_2)th switch SW1_2 disposed between the (2_1)th pad PD2_1 and the (2_2)th pad PD2_2. In this case, the main controller MC may turn off the (1_2)th switch SW1_2. Accordingly, the (2_1)th pad PD2_1 and the (2_2)th pad PD2_2 may not be electrically connected to each other. In other words, the main controller MC may apply a second gate voltage GV2 to the (2_1) pad PD2_1. The main controller MC may not apply the second gate voltage GV2 to the (2_2) pad PD2_2. In this case, the main controller MC may turn off the (1_2)th switch SW1_2 to prevent the second gate voltage GV2 from being transmitted to the (2_2)th pad PD2_2.

In an embodiment and referring to FIGS. 7A, 8A, and 8B, the main controller MC may apply the individual voltage IV to the non-connection pad NPD. For example, the main controller MC may apply the individual voltage IV to the (2_2)th pad PD2_2. In this case, the main controller MC may set the magnitude of the individual voltage IV applied to the (2_2)th pad PD2_2 by considering the magnitudes of the first to third gate voltages GV1 to GV3 applied to the connection pads CPD.

According to a first case Case 1 of a first embodiment shown in FIG. 8A, the first gate voltage GV1 and the third gate voltage GV3 may be 7V. In this case, the main controller MC may set the magnitude of the individual voltage IV to 7V, which is the same as the magnitudes of the first gate voltage GV1 and the third gate voltage GV3.

In addition, according to a second case Case 2 of the first embodiment shown in FIG. 8B, the first gate voltage GV1 may be 7V and the third gate voltage GV3 may be −7V. In this case, the main controller MC may set the magnitude of the individual voltage IV to 0V, which is an intermediate value between the magnitudes of the first gate voltage GV1 and the third gate voltage GV3. In other words, the main controller MC may set the individual voltage IV to an average value of the first gate voltage GV1 and the third gate voltage GV3.

According to an embodiment, the main controller MC may set the magnitude of the individual voltage IV to a ground voltage. However, the invention is not limited thereto.

According to an embodiment, the magnitudes of the first gate voltage GV1 and the second gate voltage GV2 (or the second gate voltage GV2 and the third gate voltage GV3) may be different from each other. In this case, when a difference between the magnitudes of the first gate voltage GV1 and the second gate voltage GV2 is large, the (1_1)th pad PD1_1 (or (2_1)th pad PD2_1) may be corroded due to a potential difference. For example, in an embodiment, the (1_1)th pad PD1_1 may overlap one of the pads disposed in the first pad area PDA-DP of the display panel DP (see FIG. 3). In this case, a conductive ball including nickel (Ni) may be disposed between the (1_1) pad PD1_1 and the above-mentioned pad. The nickel (Ni) included in the conductive ball may be oxidized by a plurality of signals that are applied to the (1_1)th pad PD1_1 and the (2_1)th pad PD2_1. In this case, the oxidized nickel (Ni) included in the conductive ball may not be reduced and may be lost due to the potential difference between the (1_1)th pad PD1_1 and the (2_1)th pad PD2_1, and thus the electrical resistance of the conductive ball or the (1_1)th pad PD1_1 may increase. Accordingly, the pixel PX (see FIG. 4) connected to the first scan line GL1 may not receive the gate voltage, and the operational reliability of the display device DD (see FIG. 4) may deteriorate.

According to an embodiment, the main controller MC may apply the individual voltage IV of an appropriate magnitude to the non-connection pad NPD to prevent corrosion in the connection pad CPD. For example, the main controller MC may set the magnitude of the individual voltage IV to be applied to the (2_2)th pad PD2_2 by considering the magnitude of the first gate voltage GV1 and/or the third gate voltage GV3. In other words, the main controller MC may set the individual voltage IV so that a potential difference between the (1_2)th pad PD1_2 (or (3_2)th pad PD3_2) and the (2_2)th pad PD2_2 is not large. Thereafter, the main controller MC may apply the set individual voltage IV to the (2_2)th pad PD2_2. Accordingly, the risk of corrosion occurring in the (1_2)th pad PD1_2 (or (3_2)th pad PD3_2) may be relatively reduced. Therefore, even if the first gate voltage GV1 supplied by the main controller MC is not transmitted to the first scan line GL1 through the (1_1)th pad PD1_1 due to corrosion in the (1_1)th pad PD1_1, the (2_1)th pad PD2_1 may normally transmit the first gate voltage GV1 to the first scan line GL1. Accordingly, the operational reliability of the display device DD is improved.

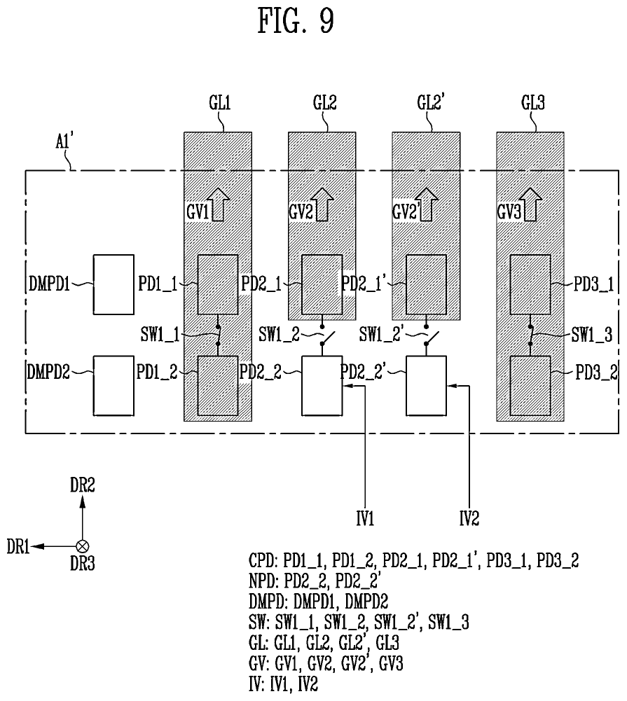

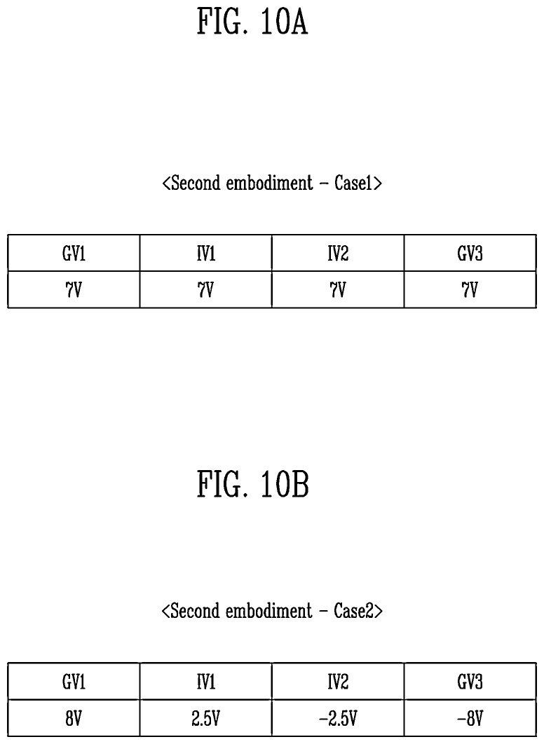

FIG. 9 is a plan view illustrating an embodiment of the first area shown in FIG. 6. FIG. 10A is a diagram illustrating an embodiment of a gate voltage applied to connection pads and an individual voltage applied to a non-connection pad in FIG. 9. FIG. 10B is a diagram illustrating an embodiment of the gate voltage applied to the connection pads and the individual voltage applied to the non-connection pad in FIG. 9.

A (1_1)th pad PD1_1, a (1_2)th pad PD1_2, a (2_1)th pad PD2_1, a (2_2)th pad PD2_2, a (3_1)th pad PD3_1, a (3_2)th pad PD3_2, a (1_1)th switch SW1_1, a (1_2)th switch SW1_2, a (1_3)th switch SW1_3, a first scan line GL1, a second scan line GL2, a third scan line GL3, a first dummy pad DMPD1, and a second dummy pad DMPD2 as shown in FIG. 9 may be described similarly to the (1_1)th pad PD1_1, the (1_2)th pad PD1_2, the (2_1)th pad PD2_1, the (2_2)th pad PD2_2, the (3_1)th pad PD3_1, the (3_2)th pad PD3_2, the (1_1)th switch SW1_1, the (1_2)th switch SW1_2, the (1_3)th switch SW1_3, the first scan line GL1, the second scan line GL2, the third scan line GL3, the first dummy pad DMPD1, and the second dummy pad DMPD2 of FIG. 7A. Hereinafter, overlapping descriptions will be omitted.

In an embodiment, a first area A1′ may include at least one connection pad CPD connected to the scan line GL. For example, the connection pads CPD may include a (2_1)th sub-pad PD2_1′ connected to a second sub-scan line GL2′.

The first area A1′ may include at least one non-connection pad NPD that is not connected to the scan line GL. For example, the non-connection pads NPD may include a (2_2)th sub-pad PD2_2′ that is not connected to the second sub-scan line GL2′.

The first area A1′ may include a (1_2)th sub-switch SW1_2′ disposed between the (2_1)th sub-pad PD2_1′ and the (2_2)th sub-pad PD2_2′. In this embodiment, the main controller MC may turn off the (1_2)th sub-switch SW1_2′. Accordingly, the (2_1)th sub-pad PD2_1′ and the (2_2)th sub-pad PD2_2′ may not be electrically connected to each other. In other words, a second sub-gate voltage GV2′ applied to the (2_1)th sub-pad PD2_1′ by the main controller MC may not be transmitted to the (2_2)th sub-pad PD2_2′.

In an embodiment and referring to FIGS. 9, 10A, and 10B, the main controller MC may apply an individual voltage IV to the non-connection pad NPD. For example, the main controller MC may apply a first individual voltage IV1 to the (2_2)th pad PD2_2. In addition, the main controller MC may apply a second individual voltage IV2 to the (2_2)th sub-pad PD2_2′. In this embodiment, the main controller MC may set the individual voltage IV by considering the magnitudes of a first gate voltage GV1 and a third gate voltage GV3 which is applied to the connection pads CPD.

According to a first case Case 1 of a second embodiment shown in FIG. 10A, the first gate voltage GV1 and the third gate voltage GV3 may be 7V. In this case, the main controller MC may set the magnitudes of the first individual voltage IV1 and the second individual voltage IV2 to 7V, which is the same as the magnitudes of the first gate voltage GV1 and the third gate voltage GV3.

In addition, according to a second case Case 2 of the second embodiment shown in FIG. 10B, the first gate voltage GV1 may be 8V and the third gate voltage GV3 may be −8V. In this case, the main controller MC may set the magnitude of the first individual voltage IV1 to 2.5V and the magnitude of the second individual voltage IV2 to −2.5V. In other words, the main controller MC may set the magnitudes of the first individual voltage IV1 and the second individual voltage IV2 to one of values between the first gate voltage GV1 and the third gate voltage GV3.

According to an embodiment, the main controller MC may set the magnitude of the individual voltage IV to a ground voltage. For example, the main controller MC may set the magnitude of at least one of the first individual voltage IV1 and the second individual voltage IV2 to the ground voltage. However, the invention is not limited thereto.

According to an embodiment, the risk of corrosion occurring in any one of a plurality of pads PD can be minimized. For example, the first area A1′ may further include the (2_2)th sub-pad PD2_2′ in addition to the (2_2)th pad PD2_2. Accordingly, even if a difference between the magnitudes of the first gate voltage GV1 and the third gate voltage GV3 is large, a potential difference between adjacent pads PD (for example, the (1_2)th pad PD1_2 and the (2_2)th pad PD2_2) can be reduced relatively stably. Accordingly, the risk of corrosion occurring in the (1_2)th pad PD1_2 can be minimized, and the display device DD (see FIG. 4) can be driven with improved reliability.

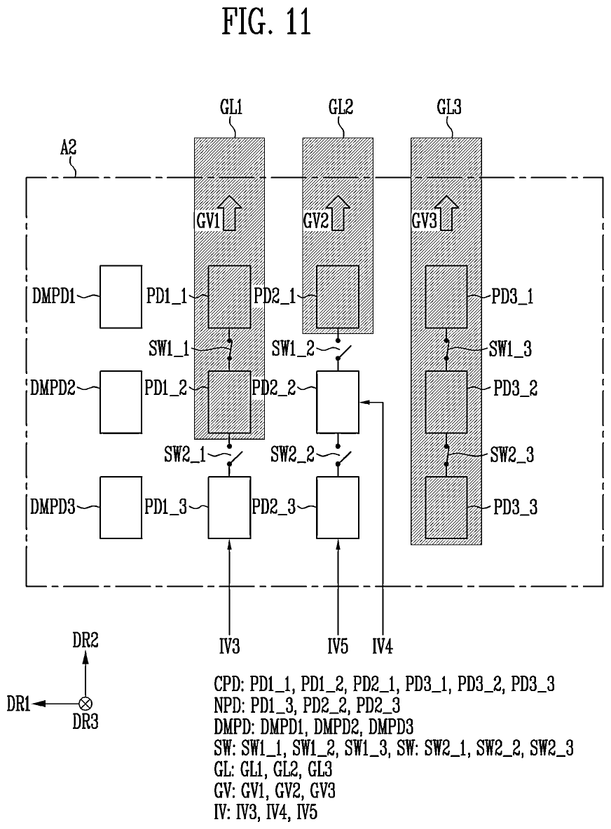

FIG. 11 is a plan view illustrating an embodiment of a second area shown in FIG. 6.

Components disposed in a second area A2 of FIG. 11 may be described similarly to the components disposed in the first area A1 of FIG. 6. Hereinafter, contents that overlap with the above-described contents will be briefly described or omitted.

In an embodiment and referring to FIG. 11, the second area A2 may include at least one connection pad CPD connected to the scan line GL. For example, the connection pads CPD may include a (3_3)th pad PD3_3 connected to the third scan line GL3.

In an embodiment, the second area A2 may include one or more non-connection pads NPD that are not connected to the scan line GL. For example, the non-connection pad NPD may include a (1_3)th pad PD1_3 that is not connected to the first scan line GL1. In addition, the non-connection pad NPD may include a (2_2)th pad PD2_2 that is not connected to the second scan line GL2.

In an embodiment, the second area A2 may include first to third dummy pads DMPD1 to DMPD3, respectively. The first to third dummy pads DMPD1 to DMPD3, respectively, may receive a ground voltage from the main controller MC (see FIG. 6). However, the invention is not limited thereto. For example, the first to third dummy pads DMPD1 to DMPD3, respectively, may be controlled to be in a floating state.

In an embodiment, the second area A2 may include a (2_1)th switch SW2_1 disposed between a (1_2)th pad PD1_2 and the (1_3)th pad PD1_3. In addition, the second area A2 may include a (2_2)th switch SW2_2 disposed between the (2_2)th pad PD2_2 and a (2_3)th pad PD2_3. As another example, the second area A2 may include a (2_3)th switch SW2_3 disposed between a (3_2)th pad PD3_2 and the (3_3)th pad PD3_3.

In an embodiment, the main controller MC may drive each of the switches SW disposed in the second area A2. In other words, each of the switches SW may be controlled according to a switch voltage WV (see FIG. 6) which is applied from the main controller MC. For example, the main controller MC may turn off the (2_1) switch SW2_1. Accordingly, the (1_2)th pad PD1_2 and the (1_3)th pad PD1_3 may not be electrically connected to each other. In addition, the main controller MC may turn off the (2_2)th switch SW2_2. Accordingly, the (2_2)th pad PD2_2 and the (2_3)th pad PD2_3 may not be electrically connected to each other. As another example, the main controller MC may turn on the (2_3)th switch SW2_3. Accordingly, the (3_2)th pad PD3_2 and the (3_3)th pad PD3_3 may be electrically connected to each other.

In an embodiment, the main controller MC may apply an individual voltage IV to the non-connection pad NPD. For example, the main controller MC may apply a third individual voltage IV3 to the (1_3)th pad PD1_3. In addition, the main controller MC may apply a fourth individual voltage IV4 to the (2_2)th pad PD2_2. As another example, the main controller MC may apply a fifth individual voltage IV5 to the (2_3) pad PD2_3.

In an embodiment, the main controller MC may set the magnitude of the individual voltage IV by considering the magnitudes of the first to third gate voltages GV1 to GV3. For example, the main controller MC may set the magnitude of the third individual voltage IV3 to the same value as the first gate voltage GV1. In addition, the main controller MC may set the magnitude of the fourth individual voltage IV4 to an intermediate value between the first gate voltage GV1 and the third gate voltage GV3. As another example, the main controller MC may set the magnitude of the fifth individual voltage IV5 by considering the third individual voltage IV3 and the third gate voltage GV3. For example, the main controller MC may set the magnitude of the fifth individual voltage IV5 to an intermediate value between the third individual voltage IV3 and the third gate voltage GV3. Accordingly, corrosion occurring in the pads PD can be minimized, and the operational reliability of the display device DD (see FIG. 6) is improved.

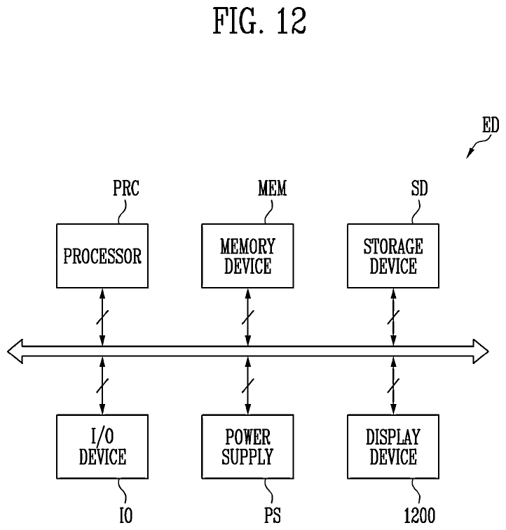

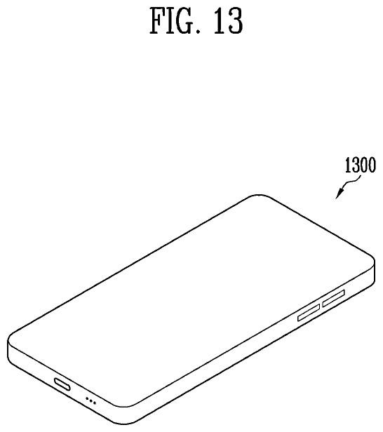

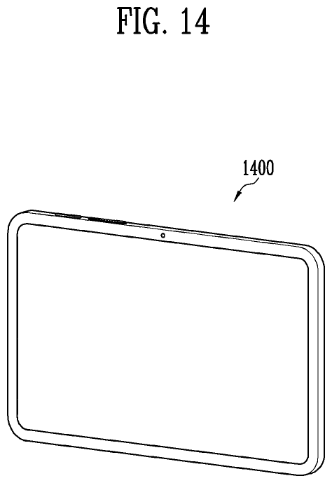

FIG. 12 is a block diagram illustrating an electronic device including a display device, according to an embodiment. FIG. 13 is a perspective view illustrating an embodiment in which the electronic device of FIG. 12 is implemented as a smartphone. FIG. 14 is a perspective view illustrating an embodiment in which the electronic device of FIG. 12 is implemented as a tablet PC.

In an embodiment and referring to FIGS. 12 to 14, an electronic device ED may include a processor PRC, a memory device MEM, a storage device SD, an input/output device IO, a power supply PS, and a display device 1200. In this case, the display device 1200 may be the display device 400 of FIG. 4. In addition, the electronic device ED may further include several ports that can communicate with a video card, a sound card, a memory card, a universal serial bus (USB) device, and the like, or with other systems. In an embodiment, as shown in FIG. 13, the electronic device ED may be implemented as a smartphone 1300. In an embodiment, as shown in FIG. 14, the electronic device ED may be implemented as a tablet PC 1400. However, these are only examples, and the electronic device ED is not limited thereto. For example, the electronic device ED may be implemented as a mobile phone, a video phone, a smart pad, a smart watch, a car navigation system, a computer monitor, a laptop, a head-mounted display devices, or the like.

The processor PRC may perform specific calculations or tasks. According to an embodiment, the processor PRC may be a microprocessor, a central processing unit, an application processor, or the like. The processor PRC may be connected to other components through an address bus, a control bus, a data bus, and the like. According to an embodiment, the processor PRC may also be connected to an expansion bus, such as a peripheral component interconnect (PCI) bus.

The memory device MEM may store data necessary for the operation of the electronic device ED. For example, the memory device MEM may include a non-volatile memory device such as an EPROM (erasable programmable read-only memory) device, an EEPROM (electrically erasable programmable read-only memory) device, a flash memory device, a PRAM (phase change random access memory) device, a RRAM (resistance random access memory) device, a NFGM (nano floating gate memory) device, a PoRAM (polymer random access memory) device, a MRAM (magnetic random access memory) device, or a FRAM (ferroelectric random access memory) device, and/or a volatile memory device such as a DRAM (dynamic random access memory) device, a SRAM (static random access memory) device, or a mobile DRAM device.

The storage device SD may include a solid state drive (SSD), a hard disk drive (HDD), a compact disc read only memory (CD-ROM), or the like.

The input/output device IO may include an input means such as a keyboard, a keypad, a touchpad, a touch screen, a microphone for voice-to-text, and a mouse, and an output means such as a speaker and a printer. According to an embodiment, the display device 1200 may be included in the input/output device IO.

The power supply PS may supply a power source necessary for the operation of the electronic device ED. For example, the power supply PS may be a power management integrated circuit (PMIC).

The display device 1200 may display an image corresponding to visual information of the electronic device ED. In this case, the display device 1200 may be an organic light emitting display device or a quantum dot light emitting display device, but the invention is not limited thereto. Moreover, the display device 1200 may be connected to other components through the buses or other communication links.

Referring to FIG. 13, a smartphone 1300 including the display device, according to an embodiment may have improved operational reliability.

Referring to FIG. 14, a tablet PC 1400 including the display device, according to an embodiment may have improved operational reliability.

According to the embodiments of the invention, a display device and an electronic device with improved operational reliability is provided by preventing corrosion occurring in pads that are included in a driving circuit.

Although specific embodiments and applications have been described herein, other embodiments and variations may be derived from the above description. Accordingly, the spirit of the invention is not limited to these embodiments, but extends to the scope of the invention. While the invention has been particularly shown and described with reference to embodiments thereof, it will be understood by those of ordinary skill in the art that various changes in form and details may be made therein without departing from the spirit or scope of the invention. Therefore, it is to be understood that the foregoing is illustrative of various embodiments and is not to be construed as limited to the specific embodiments disclosed, and that modifications to the invention, are intended to be included within the scope of the invention. Moreover, the embodiments or parts of the embodiments may be combined in whole or in part without departing from the scope of the invention.

What is claimed is:

1. A display device comprising:
a display panel including signal lines connected to one or more pixels;
a plurality of connection pads for supplying driving signals to the signal lines;
one or more non-connection pads positioned adjacent to the plurality of connection pads, wherein the one or more non-connection pads are not connected to the signal lines; and
a main controller for setting an individual voltage based on voltages of the driving signals and for applying a set of individual voltages to the non-connection pad.

2. The display device of claim 1, further comprising:
one or more switches disposed between any one of the connection pads and the non-connection pad.

3. The display device of claim 2, wherein the main controller turns off the one or more switches.

4. The display device of claim 3, wherein a magnitude of the individual voltage is the same as a magnitude of the voltages of the driving signals.

5. The display device of claim 3, wherein the individual voltage is a ground voltage.

6. The display device of claim 1, wherein the connection pads include a (1_1)th pad and a (1_2)th pad sequentially arranged in a first direction, and
wherein the non-connection pad includes a (2_2)th pad arranged to be spaced apart from the (1_2)th pad in a second direction, wherein the second direction intersects the first direction.

7. The display device of claim 6, wherein the connection pads further include a (2_1)th pad, wherein the (2_1)th pad is spaced apart from the (1_1)th pad in the second direction and spaced apart from the (2_2)th pad in a direction opposite to the first direction.

8. The display device of claim 7, further comprising:
a (1_2)th switch disposed between the (2_1)th pad and the (2_2)th pad,
wherein the main controller turns off the (1_2)th switch.

9. The display device of claim 8, wherein the connection pads further include:
a (3_1)th pad arranged to be spaced apart from the (2_1)th pad in the second direction; and
a (3_2)th pad arranged to be spaced apart from the (2_2)th pad in the second direction.

10. The display device of claim 9, wherein the main controller sets a magnitude of an individual voltage being applied to the (2_2)th pad based on a magnitude of a first voltage applied to the (1_2)th pad and a magnitude of a second voltage applied to the (3_2)th pad according to the driving signals.

11. The display device of claim 10, wherein the magnitude of the individual voltage applied to the (2_2)th pad is an average value of the magnitude of the first voltage and the magnitude of the second voltage.

12. The display device of claim 9, wherein the connection pads include a (2_1)th sub-pad arranged between the (2_1)th pad and the (3_1)th pad in the first direction, and
wherein the non-connection pads include a (2_2)th sub-pad arranged between the (2_2)th pad and the (3_2)th pad in the first direction.

13. The display device of claim 12, wherein the main controller sets the magnitude of the individual voltage being applied to the (2_2)th pad and the (2_2)th sub-pad based on a magnitude of the first voltage applied to the (1_2)th pad and the magnitude of the second voltage applied to the (3_2)th pad according to the driving signals.

14. The display device of claim 9, wherein the connection pads further include a (3_3)th pad arranged to be spaced apart from the (3_2)th pad in the first direction, and
wherein the non-connection pads further include a (1_3)th pad arranged to be spaced apart from the (1_2)th pad in the first direction, and a (2_3)th pad arranged to be spaced apart from the (2_2)th pad in the first direction.

15. The display device of claim 1, further comprising:
a scan driver generating a scan signal that is one of the drive signals,
wherein the scan driver supplies the scan signal to the one or more pixels through the signal lines.

16. A display device comprising:
a display panel including signal lines connected to one or more pixels;
a plurality of connection pads for supplying driving signals having driving signal voltages to the signal lines;
a non-connection pad positioned adjacent to the plurality of connection pads, wherein the non-connection pad is not connected to the signal lines; and
a main controller applying an individual voltage having a value which is between a highest value and a lowest value among driving signal voltages being supplied to the non-connection pad.

17. An electronic device comprising:
a processor providing input image data to a display device, wherein
the display device displays an image based on the input image data, and
wherein the display device includes:
a display panel having signal lines connected to one or more pixels;
a plurality of connection pads provided to supply driving signals to the signal lines;
one or more non-connection pads positioned adjacent to the plurality of connection pads, wherein the plurality of connection pads are not connected to the signal lines; and
a main controller for setting an individual voltage based on voltages of the driving signals and for applying a set of individual voltages to the non-connection pad.

18. The electronic device of claim 17, further comprising:
one or more switches disposed between any one of the connection pads and the non-connection pad.

19. The electronic device of claim 18, wherein the main controller turns off the one or more switches.

20. The electronic device of claim 19, wherein a magnitude of the individual voltage is the same as a magnitude of the voltages of the driving signals.
